(19) United States
(12) Patent Application Publication
(10) Pub. No.: US 2012/0167942 A1
(43) Pub. Date: Jul. 5, 2012

(54) LOW-CONCENTRATION FLAT PROFILE PHOTOVOLTAIC MODULES

(75) Inventors: James M. GEE, Albuquerque, NM (US); Manhal Aboudi, Chandler, AZ (US); Fares Bagh, Austin, TX (US)

(73) Assignee: APPLIED MATERIALS, INC., Santa Clara, CA (US)

(21) Appl. No.: 13/419,236

(22) Filed: Mar. 13, 2012

Related U.S. Application Data
(63) Continuation of application No. 12/705,941, filed on Feb. 15, 2010.
(60) Provisional application No. 61/152,361, filed on Feb. 13, 2009.

(51) Int. Cl. H01L 31/05

(52) U.S. Cl. 136/244

(57) ABSTRACT

The present invention generally relates to low-concentration photovoltaic modules. The photovoltaic modules may comprise a flexible backsheet having a plurality of electrically conductive circuit elements that have been embossed or imprinted to create optical features in the electrically conductive surface. The solar cells are then in electrical contact with the electrically conductive circuit elements to complete the photovoltaic module. By imprinting/embossing the electrically conductive circuit elements, incident solar radiation that would normally not reach the solar cells may be reflected and collected by the solar cells. Thus, substantially all of the solar radiation that is exposed to the photovoltaic module is collected by the solar cells of the photovoltaic module.

### CROSS-REFERENCE TO RELATED APPLICATIONS

This application is a continuation of co-pending U.S. patent application Ser. No. 12/705,941, filed Feb. 15, 2010, which claims benefit of U.S. Provisional Patent Application Ser. No. 61/152,361, filed Feb. 13, 2009, which is herein incorporated by reference.

### BACKGROUND OF THE INVENTION

1. Field of the Invention

Embodiments of the present invention generally relate to low-concentration photovoltaic modules.

2. Description of the Related Art

The most expensive component in a photovoltaic module for solar energy conversion is the solar cell. It is advantageous to use less expensive optical elements to concentrate the sunlight onto fewer solar cells to increase the power output of each of the most expensive components. Increasing the sunlight intensity on a solar cell can also improve the conversion efficiency because the voltage of a solar cell increases logarithmically with current and current in solar cells is linearly proportional to the solar intensity. Photovoltaic modules using optical elements to concentrate the sunlight onto a solar cell are commonly called concentrators.

Concentration photovoltaic modules are commonly classified by their “geometric concentration ratio,” which is the ratio of the optical aperture to the cell area. Higher optical concentration uses the smallest solar cell area for a given power output, but requires higher quality optics, better pointing accuracy to the sun (i.e., it is typically mounted on 1- or 2-axis tracker), and typically only converts the direct, normal component of sunlight. Very low-concentration systems have reduced pointing accuracy requirements, can potentially use a fixed orientation rather than requiring tracking systems, and can convert some or much of the diffuse (i.e., indirect) radiation.

Concentrator optics feature increased optical path length inside the photovoltaic module to concentrate the radiation. Frequently, this requires that the module has a larger depth or physical thickness. It is advantageous to design a concentrator module where the depth is similar to standard products and that does not require tracking so that the module can be used interchangeably with standard photovoltaic modules.

Solar cells in conventional modules are spaced closely together to minimize optical losses. Nevertheless, there is space required between the solar cells in the photovoltaic module to accommodate thermal expansion, manufacturing tolerances, and stress reduction in the interconnects. Light incident in between the solar cells is reflected normally and is lost through the front surface of the module if a specularly reflective backsheet is used. Much of the light incident between the solar cells is thus not redirected to adjacent solar cells, and is therefore not converted into electricity (See FIG. 1.). A known method for collecting such light internally in a photovoltaic module is by scattering light at the backsheet and confining the light by total internal reflection at the front surface of the photovoltaic module. In contrast, as shown in FIG. 2, light incident between the cells in a module with a faceted reflector can be redirected to an adjacent solar cell. This light is reflected by the faceted reflector towards the front surface of the photovoltaic module, where it is then reflected at the glass-air interface due to total internal reflection. The net result is that light is transported laterally to an adjacent solar cell surface. Thus, spacing between solar cells may be increased by use of faceted reflectors on the rear surface. It has been estimated that normally incident radiation is transported laterally a distance 3.4× the physical thickness of the module. This estimate implies that thicker modules can transport light a greater distance laterally, and that higher concentration ratios can be achieved with smaller solar cells.

Back-contact solar cells can be assembled directly to a flexible circuit during the module lamination step (“monolithic module assembly”), which eliminates the additional steps for electrical assembly of the solar cell circuit conventional photovoltaic module assembly. Monolithic module assembly has several advantages in terms of electrical performance, cost of assembly, and reduced stress for use with thinner solar cells.

There is a need in the art for a photovoltaic module that efficiently and effectively ensures that the incident solar radiation is properly reflected to the solar cells.

### SUMMARY OF THE INVENTION

The present invention generally relates to low-concentration photovoltaic modules. The photovoltaic modules may comprise a flexible backsheet having a plurality of electrically conductive circuit elements that have been embossed or imprinted to create optical features in the electrically conductive surface. The solar cells are then in electrical contact with the electrically conductive circuit elements to complete the photovoltaic module. By imprinting/embossing the electrically conductive circuit elements, incident solar radiation that would normally not reach the solar cells may be reflected and collected by the solar cells. Thus, substantially all of the solar radiation that is exposed to the photovoltaic module is collected by the solar cells of the photovoltaic module.

In one embodiment, a photovoltaic module includes a backsheet and a plurality of electrically conductive circuit elements coupled to the backsheet. The plurality of electrically conductive circuit elements having an embossed surface. A plurality of solar cells may also be coupled to the embossed surface of the electrically conductive circuit elements.

In another embodiment, a method of fabricating a photovoltaic module includes disposing a plurality of electrically conductive circuit elements over a backsheet in a predetermined pattern. The plurality of electrically conductive circuit elements have a first surface in contact with the backsheet and an embossed surface opposite the first surface. The method also includes disposing a plurality of solar cells over the plurality of electrically conductive circuit elements such that at least a portion of the plurality of electrically conductive circuit elements are exposed.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of light reflection in a conventional solar cell module.

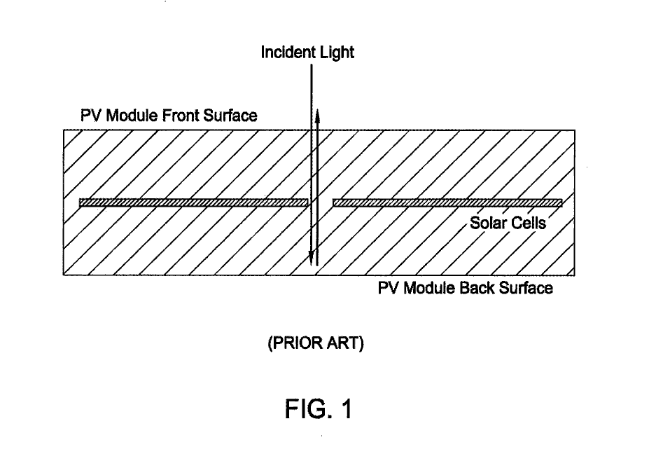

FIG. 2 is a schematic illustration of light reflection in a solar cell module having faceted reflectors.

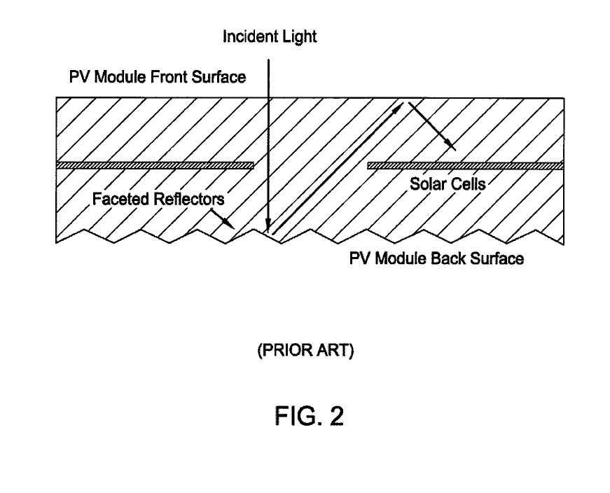

FIG. 3 is a blown up view of a photovoltaic module.

FIG. 4 is a schematic cross-sectional view of a photovoltaic module.

FIG. 5 is a cross sectional view of an embodiment of a flexible-circuit photovoltaic module backsheet comprising optical features embossed into the electrical circuit layer.

FIG. 6 is a schematic illustration of a module with asymmetric optical concentration.

FIG. 7 is a schematic illustration of a plurality of solar cells disposed over an embossed electrically conductive circuit element.

### DETAILED DESCRIPTION

The present invention generally relates to low-concentration photovoltaic modules. The photovoltaic modules may comprise a flexible backsheet having a plurality of electrically conductive circuit elements that have been embossed or imprinted to create optical features in the electrically conductive surface. The solar cells are then in electrical contact with the electrically conductive circuit elements to complete the photovoltaic module. By imprinting/embossing the electrically conductive circuit elements, incident solar radiation that would normally not reach the solar cells may be reflected and collected by the solar cells. Thus, substantially all of the solar radiation that is exposed to the photovoltaic module is collected by the solar cells of the photovoltaic module.

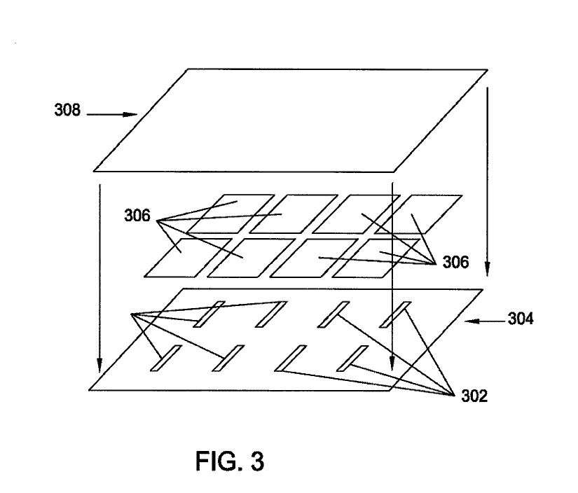

FIG. 3 is a blown up view of a photovoltaic module. FIG. 3 shows electrically conductive circuit elements 302 that are pre-patterned (or placed) onto the surface of a backsheet 304. The backsheet 304 provides several functions in photovoltaic modules, such as environmental protection, resistance to cuts and mechanical abrasion, and electrical isolation. Backsheets frequently consist of different layers of materials to provide these functions. For example, the backsheet 304 may comprise an outer layer of polyvinyl fluoride that is roll laminated onto polyester with an adhesive layer. The pattern of electrically conductive circuit elements 302 is selected based on the electrical requirements of the module to be manufactured and in part dictated by the dimensions of the solar cells to be used on the module. Specifically, the electrically conductive circuit elements 302 are positioned so that when they are connected by the solar cells 306, an electric circuit that is capable of generating power is created. The decisions about how precisely to configure the electrical circuit and where exactly to locate the electrically conductive circuit elements 302 relative to each other may be tailored to suit the needs of the user.

Back-contact solar cells 306 are positioned atop the electrically conductive circuit elements 302 so that the contacts of the solar cells 306 complete the circuit. An electrically conductive material is provided between the solar cell contacts and the electrically conductive circuit elements 302 on the backsheet 304 to complete the electrical circuit of the photovoltaic module. A sheet of polymer encapsulation is positioned over the surfaces of the solar cells 306 and the backsheet 304. Finally a cover 308 of glass is placed atop the assembled elements. The module is then sealed using heat and pressure or another sealing method suited to the particular polymer encapsulation material selected.

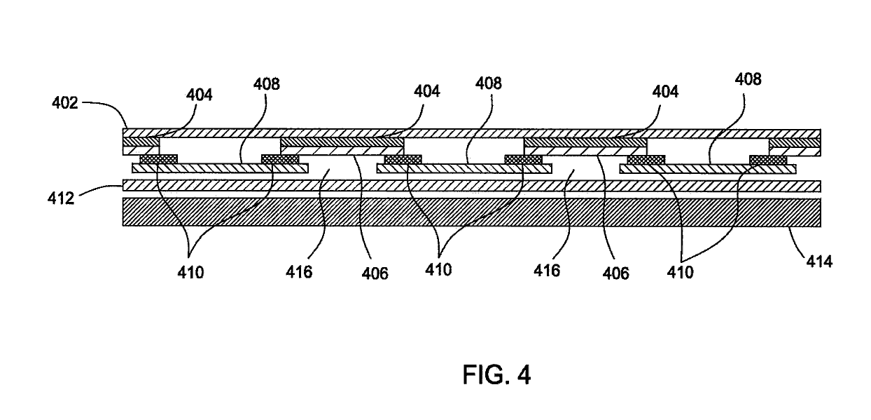

FIG. 4 is a schematic cross-sectional view of a photovoltaic module. The photovoltaic module includes a backsheet 402 and a plurality of electrically conductive circuit elements 404 disposed thereon in a predetermined pattern. As will be discussed below, the electrically conductive circuit elements 404 are embossed. If necessary to ensure adequate adhesion between the electrically conductive circuit elements 404 and the solar cells 408, an electrically conductive and protective layer 406 may be present over the electrically conductive circuit elements 404. The protective layer 406 functions to protect the electrically conductive circuit elements 404 from the environment where the electrically conductive circuit elements 404 may oxidize and lose their conductivity. It is also useful to choose a coating that has similar chemical characteristics to the electrical attachment material in order to avoid corrosion. In one embodiment, the protective layer 406 may comprise silver and may have a thickness of up to about 1000 Angstroms. The protective layer 406 may be deposited by any well known deposition means such as electrochemical deposition.

To electrically connect and adhere the electrical circuit elements 404 to the solar cells 408, an electrically conductive attachment layer 410 may be present. This layer is used in specific portions of the solar cell that were designed for electrical connection (“terminals”). The terminals provide regions on the solar cells 408 for electrical connection to the electrically conductive circuit elements 404. The electrically conductive attachment layer 410 may comprise an electrically conductive adhesive such as an epoxy with electrically conductive particles, such as silver, carbon, metal alloys with low liquidus temperatures, etc., therein. Alternatively, the electrically conductive attachment layer 410 may be a solder. The electrically conductive attachment layer 410 may be present over the entire surface of the protective layer 406 (so long as the adhesive layer does not have a negative impact upon the reflection capabilities of the protective layer 406). In one embodiment, the electrically conductive attachment layer 410 may be present in select locations between the solar cell 408 and the protective layer 406. Encapsulating material 412 and a cover 414 are also present. Adjacent solar cells 408 may be spaced apart by a gap 416 such that the electrically conductive circuit elements 404, or adhesive layer 406 is present, may be exposed.

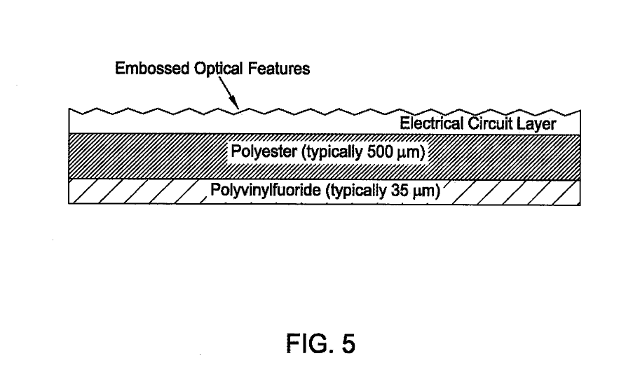

The embodiments discussed herein describe integration of faceted reflectors, diffractive gratings, or other optical structures in a flexible circuit backsheet material for monolithic module assembly. The advantage of this approach is that there are little additional costs for integration of the optical components into the module since a highly reflective metal layer is typically already required for the flexible circuit. The additional processing step for the flexible circuit backsheet typically comprises printing or embossing of the optical features into the metal circuit surface. As used throughout the specification and claims, the term “embossing” means any method of creating features, including but not limited to imprinting, mechanical scribing, etching, plating, and chemical texturing. The metal circuit preferably comprises either copper or aluminum having a thickness preferably of between about 25 micrometers and about 125 micrometers. The metal circuit layer is frequently coated with a bondable material (e.g., silver) disposed therein to improve the bonding of the cell to the flexible circuit with the conductive adhesive or solder. The bondable material also functions to protect the metal circuit layer from a corrosive environment. This bondable coating is preferably highly reflective metal. The thickness of the embossed features is preferably less than the thickness of the metal circuit layer in order to not interfere with its primary role as an electrical connection between solar cells. The feature size is therefore preferably between approximately 0.5 micrometers and approximately 50 micrometers. A representative cross section of such a flexible circuit is presented in FIG. 5. Such a flexible circuit with embossed optical features can be used for monolithic module assembly of photovoltaic modules using back-contact solar cells with few changes in the process.

A simple faceted reflector with an included angle of 120 degrees has an acceptance angle of about 25 degrees. More elaborate optical structures, including adding optical structures to the glass surface, may have larger acceptance angles. The optics can be designed to work with a variety of solar cell sizes and shapes to achieve different concentration ratios with different sensitivities to module orientation. Some representative examples of the present invention are discussed below.

Low-Concentration with Large Solar Cells

A typical size for a silicon solar cell is 156 millimeters by 156 millimeters. An optical element on the backsheet preferably enables the intercell spacing to be increased to approximately 14.8 millimeters, which corresponds to a geometric concentration ratio of 1.2×. The optical efficiency with faceted reflectors can be quite high since the lateral transport distance is over 15 millimeters (3.4 times the approximate 5 millimeter thickness of the photovoltaic module).

Use with Pseudo-Square and Arbitrarily Shaped Solar Cells

Monocrystalline silicon ingot growth generally produces crystalline ingots. Square wafers cut from such round ingots generally have rounded corners that lose about 0.5 to 2.7 percent of the area subtended by the square dimensions. A faceted reflector and/or other optical elements can be used to recover much of this lost light. In addition, faceted reflectors could be used to enhance the performance of any shape solar cell. Hence, round or half-round cells could be used.

Use with Small-Area Solar Cells

The lateral transport of optical radiation is limited by the thickness of the module. The geometric concentration ratio is therefore maximized by using smaller cells. The geometric concentration ratio is approximately 1.2 (with large area cells) to over 2× (with small-area cells). In this case, the edge dimension of the cell is preferably selected to be approximately the same as the lateral transport distance of optical radiation, for example approximately 15 millimeters if using a module with a total thickness of about 5 millimeters. Since optical efficiency of the lateral transport of radiation decreased with off-normal incidence, this approach is likely to be optimized for tracking systems.

### Asymmetric Optical Concentration

The solar angle of incidence is the angle between the sun position and the surface normal of the module. The solar angle of incidence is a function of the location of the module (latitude), module orientation, and position of the sun, which is a function of the time of day and of the season. The largest change in solar position (up to 180 degrees) occurs daily between sunrise and sunset (“solar azimuth”), while the seasonal variation in angle relative to the horizon (“solar altitude”) is slower and more limited in range. The seasonal range of altitude is determined by the latitude of the location. Energy production of a module is dramatically reduced when the solar angle of incidence is outside the acceptance angle of the optical concentrator.

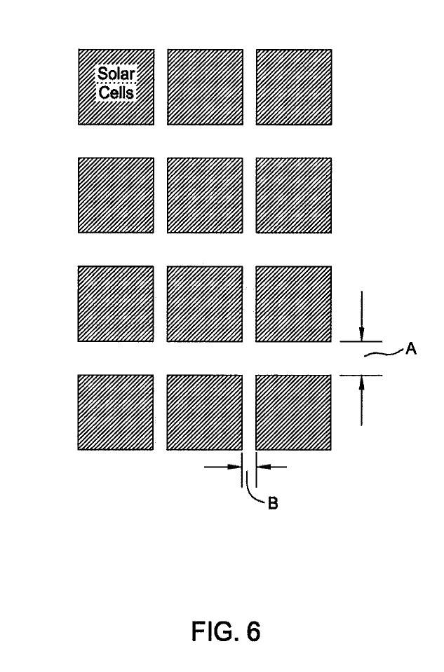

Mounting the module on a structure that tracks the position of the sun maximizes the optical efficiency of the concentration and energy production. However, it is advantageous to design the module for fixed-position mounting for widest application. The optical concentrator can be designed to minimize the effect of limited acceptance angle and fixed orientation by using an asymmetric design so that the optical concentration and acceptance angle are different in altitude and azimuth. A larger acceptance angle with less optical concentration in azimuth minimizes energy production loss due to the daily variation in azimuth, while a larger concentration with lower acceptance angle can be used in altitude where the range of variation is less. Alternatively, the opposite (i.e., larger concentration in azimuth compared to altitude) might be used if a single-axis tracking system is used. In practice, this asymmetry implies that the solar cells are spaced further apart with the faceted optical concentration in one dimension compared to the opposite dimension. As shown in FIG. 6, the wide spacing in the vertical direction (A) has a greater optical concentration compared with the narrower spacing in the horizontal axis (B). The module is preferably mounting with the vertical axis mounted vertically to achieve this benefit for systems without tracking.

The plurality of electrically conductive circuit elements can be arranged in a predetermined pattern such that such that at least a two by two matrix of solar cells (when placed over the electrically conductive circuit elements) are present in the module. As shown in FIGS. 4 and 5, the solar cells are not disposed over the electrically conductive circuit elements such that the electrically conductive circuit elements are covered by the solar cells. Rather, the solar cells are placed such that at least a portion of the electrically conductive circuit elements are exposed such that solar radiation may impact the electrically conductive circuit elements. As shown in FIG. 6, a first solar cell is spaced apart from a first adjacent solar cell by a first distance in the horizontal direction “B” and is also spaced apart from a second adjacent solar cell by a second distance in the vertical direction “A” that is larger than the first distance. The solar cells may be spaced apart such that three solar cells, nonlinearly arranged, may be spaced apart by different distances.

The increase in spacing between adjacent solar cells is possible because the spaces between the solar cells are filled (from the sun's perspective) by highly reflective electrically conductive circuit elements that will reflect the solar radiation that impacts the electrically conductive circuit elements. Thus, substantially all of the solar radiation that would impact the photovoltaic module may be collected. As one can easily understand, the total surface area of the photovoltaic module may thus be increased (due to the increased spacing between the adjacent solar cells) and the efficiency of the solar cells may be increased (due to the ability of the solar cells to collect the solar radiation that initially impacts the electrically conductive circuit elements. Additionally, the embossed electrically conductive circuit elements may permit the photovoltaic modules to utilize smaller solar cells and even different sized solar cells to create the photovoltaic module, which may reduce photovoltaic module manufacturing costs. The embossed electrically conductive circuit elements may also permit photovoltaic modules to be manufactured that have a shape other than rectangular.

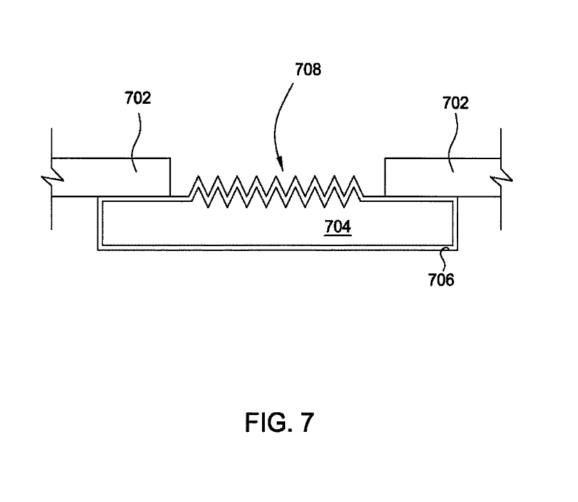

FIG. 7 is a schematic illustration of a plurality of solar cells disposed over an embossed electrically conductive circuit element. As shown in FIG. 7, the solar cells 702 are disposed over the electrically conductive circuit element 704. In one embodiment, the electrically conductive circuit element 704 comprises copper, aluminum or combinations thereof. It is to be understood that other materials may be utilized as well.

The electrically conductive circuit element 704 may be coated with a layer 706 that is both more reflective than the electrically conductive circuit element 704 and also better suited to withstand the environment within which it will be situated. For example, copper readily oxidizes when exposed to air or to moisture inside the photovoltaic module, and could easily reduce electrically conductivity between the solar cell 702 and the electrically conductive element 704. Thus, when copper is the material of the electrically conductive circuit element 704, it would be beneficial to prevent the copper from being exposed to air or moisture. One material of particular interest for layer 706 is silver. The silver may be coated over all surfaces of the electrically conductive circuit element 704, even the embossed portion 708. It is to be understood that material other than silver may be utilized for layer 706. For example, alloys that have low melting points may be used. An adhesive material or solder may be used to couple the solar cell 702 to the layer 706.

As shown in FIG. 7, the electrically conductive circuit element 704 has an embossed portion 708 and substantially planar (relative to the embossed portion 708) portion on the surface upon which the solar cells 702 are disposed. Additionally, the surface opposite the embossed surface is also substantially planar relative to the embossed portion 708. It is to be understood that the entire upper surface may be embossed such that the solar cell interfaces with the embossed surface.

The solar cells 702 are disposed over the substantially planar portions and not over the embossed portion 708. The planar portion has an increased area of contact between the solar cell 702 and the electrically conductive circuit element 704 relative to the embossed portion 708 which leads to better electrically contact between the solar cell 702 and the electrically conductive circuit element 704. The embossed portion 708 is disposed adjacent the edge of the solar cell 702 such that the light may reflect from the embossed portion 708 and ultimately be collected by the solar cell 702.

By embossing the electrically conductive circuit elements, the solar radiation that is not directly collected by the solar cells may be reflected back to the solar cells. The highly reflective material reflects the solar radiation back up to the front surface of the photovoltaic module where it is reflected back to be collected by the solar cell. The embossed surface permits the solar radiation to be reflected back towards the front surface at an angle so that the solar radiation will impact the front surface at an angle and then reflect at an angle back to the solar cell. Granted, the highly reflective material of the electrically conductive circuit elements, the highly reflective material for the optional adhesion layer, and the highly reflective back of the front surface may not reflect all solar radiation, but any solar radiation that is reflected and ultimately collected by the solar cells is more than would otherwise be present in absence of the embossed surface. Therefore, the embossed electrically conductive circuit elements improve photovoltaic power output.

While the foregoing is directed to embodiments of the present invention, other and further embodiments of the invention may be devised without departing from the basic scope thereof, and the scope thereof is determined by the claims that follow.

1. A substrate for interconnecting photovoltaic devices, comprising:
a flexible backsheet; and
a plurality of electrically conductive circuit elements coupled to the flexible backsheet, the plurality of electrically conductive circuit elements having an embossed surface, and comprising a metal selected from a group consisting of aluminum or copper.

2. The substrate of claim 1, wherein the plurality of electrically conductive circuit elements form part of a circuit used to interconnect two or more back contact solar cells.

3. The substrate of claim 2, wherein the flexible backsheet further comprises a material selected from a group consisting of polyvinyl fluoride and polyester.

4. The substrate of claim 1, wherein the flexible backsheet further comprises:
a first layer; and
a second layer that is disposed between the first layer and the plurality of electrically conductive circuit elements, wherein the second layer comprises polyester.

5. A substrate for interconnecting photovoltaic devices, comprising:
a flexible backsheet;
a plurality of electrically conductive circuit elements coupled to the flexible backsheet, the plurality of electrically conductive circuit elements comprising aluminum or copper; and
a bondable material layer disposed on a surface of each of the plurality of electrically conductive circuit elements, wherein the bondable material layer comprises a metal other than aluminum.

6. The substrate of claim 5, wherein the plurality of electrically conductive circuit elements form part of a circuit used to interconnect two or more back contact solar cells.

7. The substrate of claim 5, wherein the plurality of electrically conductive circuit elements comprise aluminum, and the bondable material layer further comprises silver.

8. The substrate of claim 5, wherein the plurality of electrically conductive circuit elements comprise copper, and the bondable material layer further comprises silver.

9. The substrate of claim 5, wherein the bondable material layer further comprises a metal other than copper.

10. The substrate of claim 5, wherein the flexible backsheet further comprises a material selected from a group consisting of polyvinyl fluoride and polyester.

11. The substrate of claim 5, wherein the flexible backsheet further comprises a first layer and a second layer that is disposed between the first layer and the plurality of electrically conductive circuit elements, wherein the second layer comprises polyester.

12. A substrate for interconnecting photovoltaic devices, comprising:
a flexible backsheet comprising a first layer and a second layer;
a plurality of electrically conductive circuit elements coupled to the flexible backsheet, the plurality of electrically conductive circuit elements having an embossed surface, and comprising a metal selected from a group consisting of aluminum and copper; and
a bondable material layer disposed on a surface of each of the plurality of electrically conductive circuit elements, wherein the bondable material layer comprises a metal other than aluminum or copper.

13. The substrate of claim 12, wherein the feature size of the plurality of embossed electrically conductive circuit elements is between about 5 micrometers and about 50 micrometers.

14. The substrate of claim 12, wherein the first layer comprises polyvinyl fluoride and the second layer comprises a polyester.

15. The substrate of claim 14, wherein the second layer is disposed between the first layer and the plurality of electrically conductive circuit elements.

16. The substrate of claim 12, wherein the plurality of electrically conductive circuit elements comprise aluminum, and the bondable material layer further comprises silver.

17. The substrate of claim 12, wherein the plurality of electrically conductive circuit elements comprise copper, and the bondable material layer further comprises silver.

18. The substrate of claim 12, wherein the plurality of electrically conductive circuit elements form part of a circuit used to interconnect two or more back contact solar cells.
